(19) United States
(12) Patent Application Publication
(10) Pub. No.: US 2025/0044713 A1
(43) Pub. Date: Feb. 6, 2025

(54) SUBSTRATE PROCESSING APPARATUS AND SUBSTRATE PROCESSING METHOD

(71) Applicant: Tokyo Electron Limited, Tokyo (JP)

(72) Inventor: Toshiaki Odaka, Kikuchi-gun (JP)

(21) Appl. No.: 18/792,948

(22) Filed: Aug. 2, 2024

(30) Foreign Application Priority Data
Aug. 4, 2023 (JP) 2023-127721

(51) Int. Cl. G03F 7/00

(52) U.S. Cl. CPC G03F 7/70991; G03F 7/7075; G03F 7/70866

(57) ABSTRACT

A substrate processing apparatus includes a dry lithography device configured to perform a lithography process on a substrate mainly by a gas; and a connector configured to connect the dry lithography device to an exposurer configured to expose the substrate. The connector includes a transfer space which is adjacent to an exposure space of the exposurer and through which the substrate is transferred between the exposurer and the dry lithography device.

### CROSS-REFERENCE TO RELATED APPLICATION

This application claims the benefit of Japanese Patent Application No. 2023-127721 filed on Aug. 4, 2023, the entire disclosure of which is incorporated herein by reference.

### TECHNICAL FIELD

The various aspects and embodiments described herein pertain generally to a substrate processing apparatus and a substrate processing method.

### BACKGROUND

Patent Document 1 discloses a substrate processing apparatus including a cassette station for carrying a substrate into/out of the apparatus, a processing device configured to perform various kinds of processes on the substrate in an atmospheric atmosphere, a transfer device, an interface device, and an EUV exposure device. The transfer device is configured to transfer the substrate between the processing device and the interface device. The EUV exposure device is configured to perform, using an EUV light source, an exposure process on the substrate disposed in a vacuum chamber evacuated to a vacuum. The interface device includes a load lock chamber configured to switch its inside between a vacuum state and an atmospheric state, and is configured to transfer the substrate between the transfer device and the EUV exposure device.
Patent Document 1: Japanese Patent Laid-open Publication No. 2010-123732.

### SUMMARY

In an exemplary embodiment, a substrate processing apparatus includes a dry lithography device configured to perform a lithography process on a substrate mainly by a gas; and a connector configured to connect the dry lithography device to an exposurer configured to expose the substrate. The connector includes a transfer space which is adjacent to an exposure space of the exposurer and through which the substrate is transferred between the exposurer and the dry lithography device.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is a side view schematically illustrating an example (first example) of a substrate processing system;

FIG. 2 is a top view schematically illustrating the substrate processing system of FIG. 1;

FIG. 3 is a top view schematically illustrating another example (second example) of the substrate processing system;

FIG. 4 is a top view schematically illustrating yet another example (third example) of the substrate processing system;

FIG. 5 is a side view schematically illustrating still yet another example (fourth example) of the substrate processing system;

FIG. 6A is a side view schematically illustrating still yet another example (fifth example) of the substrate processing system, and FIG. 6B is a side view schematically illustrating still yet another example (sixth example) of the substrate processing system;

FIG. 7A is a top view schematically illustrating still yet another example (seventh example) of the substrate processing system, and FIG. 7B is a top view schematically illustrating still yet another example (eighth example) of the substrate processing system; and

FIG. 8 is a top view schematically illustrating still yet another example (ninth example) of the substrate processing system.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In the following description, same parts or parts having same functions will be assigned same reference numerals, and redundant description thereof will be omitted. Further, in the present specification, when referring to the top, bottom, right, and left of the drawings, the directions of the symbols in the drawings shall be used as a reference.

### [Configuration of Substrate Processing System]

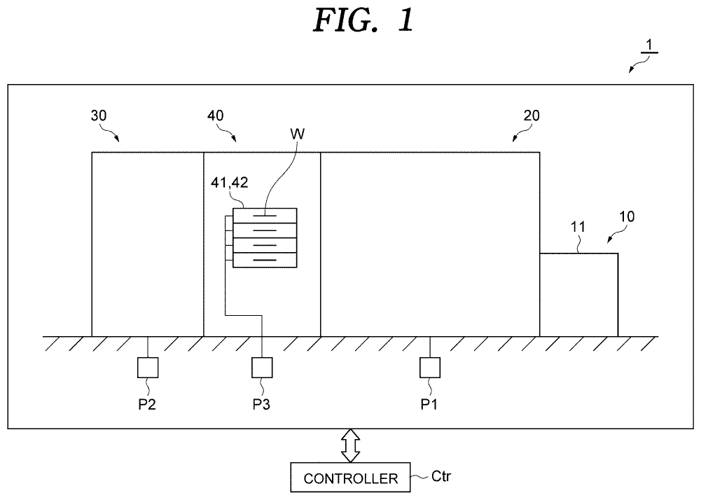

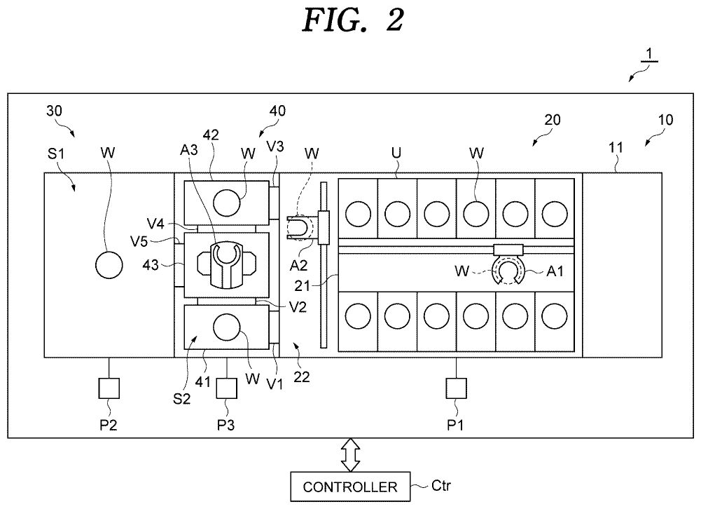

First, referring to FIG. 1 and FIG. 2, a substrate processing system 1 (substrate processing apparatus) configured to process a substrate W will be explained. The substrate processing system 1 includes a carry-in/out station 10, a dry lithography device 20, an exposure device 30, a connection station 40 (connector), pressure regulators P1 to P3, and a controller Ctr (control device). The carry-in/out station 10, the dry lithography device 20, the connection station 40, and the exposure device 30 may be arranged in a row in this order in a horizontal direction, for example.

The substrate W may have a circular plate shape, or may have a plate shape other than the circular shape, such as a polygonal shape. The substrate W may have a cutout portion where a part of the substrate W is cut out. The cutout portion may be, by way of example, a notch (a U-shaped or V-shaped groove, or the like), or may be a linear portion (so-called orientation flat) extending in a straight line shape. The substrate W may be, by way of non-limiting example, a semiconductor substrate (silicon wafer), a glass substrate, a mask substrate, a FPD (Flat Panel Display) substrate, or any of various other types of substrates. The substrate W may have a diameter ranging from, e.g., about 200 mm to about 450 mm.

The carry-in/out station 10 includes a placement table 11 configured to place at least one carrier (not shown) thereon. The carrier is configured to accommodate therein at least one substrate W hermetically. The carrier includes an opening/closing door through which the substrate W is carried in and out. The placement table 11 may be provided with a load lock chamber (not shown).

The load lock chamber is configured such that the internal pressure thereof can be adjusted between an atmospheric pressure and a pressure less than the atmospheric pressure. When transferring the substrate W from the carrier to the dry lithography device 20, the substrate W may be placed in the load lock chamber from the carrier, the inside of the load lock chamber may be decompressed, and the substrate W may be then delivered from the load lock chamber to the dry lithography device 20. When transferring the substrate W from the dry lithography device 20 to the carrier, the substrate W may be placed in the load lock chamber from the dry lithography device 20, the inside of the load lock chamber may be returned to the atmospheric pressure, and the substrate W may be delivered from the load lock chamber into the carrier.

The internal pressure of the load lock chamber may be adjusted by controlling the controller Crt to control an operation of an exhaust pump (not shown) connected to the load lock chamber and an opening/closing of a gas inlet valve (not shown). The substrate W may be delivered between the carrier, the load lock chamber, and the dry lithography device 20 by controlling the controller Ctr to control an operation of a transfer arm (not shown) provided at the placement table 11.

The dry lithography device 20 is configured to perform a lithography process on the substrate W mainly by a gas. To this end, the inside of the dry lithography device 20 is set into a decompressed state lower than the atmospheric pressure. Here, in the present specification, the lithography process by the dry lithography device 20 includes, for example, various types of processes of patterning a surface of the substrate W, such as a processes of forming a photoreactive thin film on the surface of the substrate W, a developing processes on the photoreactive thin film after being exposed, a heat treatment on the substrate W, and an etching processes on the substrate W (excluding an exposure processes on the photoreactive thin film). The photoreactive thin film includes, by way of non-limiting example, a metal-containing thin film having high absorptivity for EUV, a resist film, and the like. The gas used to process the substrate W in the dry lithography device 20 may be a gas containing an organic solvent or a gas containing an acid. Further, in the lithography processes of the substrate W in the dry lithography device 20, a liquid such as a processing liquid may be partially used.

The dry lithography device 20 includes, as illustrated in detail in FIG. 2, transfer sections 21 and 22, and a plurality of lithography chambers U.

The transfer section 21 extends horizontally in a first direction (a left-and-right direction in FIG. 2) in which the carry-in/out station 10, the dry lithography device 20, the exposure device 30, and the connection station 40 are arranged. The transfer section 21 is provided with a transfer arm A1 therein. The transfer arm A1 is configured to be movable horizontally in the first direction, movable up and down in a vertical direction, pivotable around a vertical axis, and movable forward and backward based on a control signal from the controller Ctr. The transfer arm A1 is configured to transfer the substrate W between the load lock chamber, the lithography chamber U, and the transfer section 22.

The transfer section 22 extends horizontally in a second direction (a widthwise direction of the dry lithography device 20; an up-and-down direction in FIG. 2) intersecting the first direction. The transfer section 22 is provided with a transfer arm A2 therein. The transfer arm A2 is configured to be movable horizontally in the second direction, movable up and down in a vertical direction, pivotable around a vertical axis, and movable forward and backward based on a control signal from the controller Ctr. The transfer arm A2 is configured to transfer the substrate W between the transfer section 22 and the connection station 40 (pressure regulation chambers 41 and 42 to be described later).

The plurality of lithography chambers U are arranged in a row along the first direction (the left-and-right direction in FIG. 1) on both sides of the transfer section 21. Alternatively, although not shown, the plurality of lithography chambers U may be arranged in a row along the first direction (the left-and-right direction in FIG. 1) on one side of the transfer section 21. The lithography chamber U is configured to perform a preset lithography process (for example, a process of forming a photoreactive thin film on the surface of the substrate W, a developing process on the photoreactive thin film after being exposed, a heat treatment on the substrate W, an etching process on the substrate W, and so forth) on the substrate W.

The exposure device 30 is configured to perform, in an exposure space S1 therein, an exposure process (for example, pattern exposure) on the photoreactive thin film formed on the surface of the substrate W in the dry lithography device 20. For example, the exposure device 30 may be configured to selectively radiate EUV light (having a wavelength of 13.5 nm) to an exposure target portion of the photoreactive thin film.

The connection station 40 is configured to connect the dry lithography device 20 and the exposure device 30. The connection station 40 is adjacent to the dry lithography device 20 and the exposure device 30, as illustrated in FIG. 1 and FIG. 2. Alternatively, the connection station 40 does not need to be adjacent to the dry lithography device 20. That is, another device or the like may be disposed between the connection station 40 and the dry lithography device 20.

The connection station 40 may include the pressure regulation chambers 41 and 42 and a transfer chamber 43, as shown in FIG. 2. As illustrated in FIG. 1, each of the pressure regulation chamber 41 and the pressure regulation chamber 42 of the connection station 40 may be plural in number. The plurality of pressure regulation chambers 41 may be stacked in a vertical direction or may be arranged in a horizontal direction. The plurality of pressure regulation chambers 42 may be stacked in a vertical direction or may be arranged in a horizontal direction. As illustrated in FIG. 1, for example, each of the pressure regulation chambers 41 and 42 has an internal space in which one substrate W can be placed, and may be sufficiently small in size as compared to the connection station 40.

The pressure regulation chamber 41 is connected to an internal space of the dry lithography device 20 via a gate valve V1. The pressure regulation chamber 41 is connected to an internal space of the transfer chamber 43 via a gate valve V2. The pressure regulation chamber 42 is connected to the internal space of the dry lithography device 20 via a gate valve V3. The pressure regulation chamber 42 is connected to the internal space of the transfer chamber 43 via a gate valve V4.

The transfer chamber 43 is connected to the exposure space S1 of the exposure device 30 via a gate valve V5. The transfer chamber 43 is provided with a transfer arm A3 therein. The transfer arm A3 is configured to be movable up and down in a vertical direction, pivotable around a vertical axis, and movable forward and backward based on a control signal from the controller Ctr. The transfer arm A3 is configured to transfer the substrate W between the pressure regulation chambers 41 and 42 and the exposure device 30.

The gate valves V1 to V5 are configured to be opened and closed based on a control signal from the controller Ctr. With the gate valves V1 and V3 opened, the controller Ctr controls the transfer arms A2 and A3 to carry the substrate W in and out between the inside of the pressure regulation chambers 41 and 42 and the dry lithography device 20. With the gate valve V5 opened, the controller Ctr controls the transfer arm A3 to carry the substrate W in and out between the inside of the transfer chamber 43 and the exposure space S1 of the exposure device 30. That is, the insides of the pressure regulation chambers 41 and 42 and the transfer chamber 43 are configured as a transfer space S2 in which the substrate W is transferred between the dry lithography device 20 and the exposure device 30. In the example of FIG. 2, the transfer space S2 is adjacent to the internal space of the dry lithography device 20, and is adjacent to the exposure space S1 of the exposure device 30.

The pressure regulators P1 to P3 are configured to regulate a pressure of an internal space of a place to which each of them is connected. Each of the pressure regulators P1 to P3 may include an exhaust pump (not shown) and a gas inlet valve (not shown). The exhaust pump may be, for example, a turbo molecular pump. An operation of the exhaust pump and opening/closing of the gas inlet valve may be controlled by the controller Ctr.

The pressure regulator P1 is connected to the dry lithography device 20. The pressure regulator P1 may decompress the lithography chamber U to a vacuum of about 1×10⁻⁵ Pa to about 1×10⁻³ Pa (within a range of ‘high vacuum’ defined in JIS Z 8261-1:1999). The pressure regulator P1 may decompress the transfer sections 21 and 22 to a vacuum of about 1 Pa to about 100 Pa (within a range of ‘medium vacuum’ defined in JIS Z 8261-1:1999).

The pressure regulator P2 is connected to the exposure device 30. The pressure regulator P2 may decompress the exposure space S1 of the exposure device 30 to a vacuum of about 1×10⁻⁸ Pa to about 1×10⁻⁵ Pa (within a range of ‘ultra-high vacuum’ defined in JIS Z 8261-1:1999).

The pressure regulator P3 (decompressor) is connected to the pressure regulation chambers 41 and 42 and the transfer chamber 43. The pressure regulator P3 may regulate the internal pressure of the transfer space S2 of the pressure regulation chambers 41 and 42 and the transfer chamber 43 between a pressure equivalent to the internal pressure of the transfer sections 21 and 22 and a pressure equivalent to the internal pressure of the exposure space S1 (that is, within a range from medium vacuum to ultra-high vacuum). The pressure regulator P3 may decompress the transfer space S2 when the substrate W is transferred in the transfer space S2, and may decompress the transfer space S2 all the time during the operation of the substrate processing system 1.

As the pressure regulators P1 to P3 are operated in this way, the insides of the dry lithography device 20, the exposure device 30 and the connection station 40 are maintained in a decompressed state (vacuum state). For this reason, during the transfer of the substrate W between the dry lithography device 20 and the exposure device 30 through the transfer space S2 of the connection station 40, the transfer space S2 is decompressed to a pressure less than atmospheric pressure by the pressure regulator P3. As a result, a progress of a reaction of the photoreactive thin film is suppressed during the transfer of the substrate W.

When the substrate W is transferred through the transfer space S2, the gate valves V2 and V4 may be left open. That is, when carrying the substrate W to/from the pressure regulation chambers 41 and 42, the gate valves V1 and V3 may be opened while the gate valve V5 is closed. When carrying the substrate W to/from the exposure device 30, the gate valve V5 may be opened while the gate valves V1 and V3 are closed. Alternatively, when the substrate W is transferred through the transfer space S2, the gate valves V2 and V4 may also be opened and closed. That is, when carrying the substrate W to/from the pressure regulation chambers 41 and 42, the gate valves V1 and V3 may be opened while the gate valves V2 and V4 are closed. When carrying the substrate W between the pressure regulation chambers 41 and 42 and the transfer space S2, the gate valves V2 and V4 may be opened while the gate valves V1, V3 and V5 are closed. When carrying the substrate W to/from the exposure device 30, the gate valve V5 may be opened while the gate valves V2 and V4 are closed.

The controller Ctr is configured to control the substrate processing system 1 partially or in overall.

### [Substrate Processing Method]

Now, with reference to FIG. 1 and FIG. 2, a method of processing the substrate W by the substrate processing system 1 will be discussed. Further, in the process of the substrate W, the insides of the dry lithography device 20, the exposure device 30 and the connection station 40 are all decompressed to a pressure lower than the atmospheric pressure.

First, the substrate W is taken out from the carrier in the carry-in/out station 10, and is then carried from the carry-in/out station 10 into the dry lithography device 20. Next, the lithography process is performed on the substrate W in the lithography chamber U, so that the photoreactive thin film is formed on the surface of the substrate W. Thereafter, the substrate W is transferred to the exposure device 30 through the transfer space S2 of the connection station 40. Then, the exposure process is performed on the photoreactive thin film formed on the surface of the substrate W.

Subsequently, the substrate W is transferred to the dry lithography device 20 through the transfer space S2 of the connection station 40. Then, in the lithography chamber U, the lithography process is performed on the substrate W, and the developing process on the photoreactive thin film after being exposed and the etching process on the substrate W are performed. Thereafter, the substrate W is transferred from the dry lithography device 20 to the carry-in/out station 10 and returned back into the carrier. Through these operations, the process of the substrate W is completed.

### [Effects]

According to the above-described exemplary embodiment, the connection station 40 is adjacent to the exposure device 30, and the substrate W is transferred between the dry lithography device 20 and the exposure device 30 through the transfer space S2 of the connection station 40. With this configuration, a transfer path of the substrate W between the dry lithography device 20 and the exposure device 30 is shortened. Therefore, the dry lithography process can be performed efficiently.

According to the above-described exemplary embodiment, since the transfer space S2 is decompressed by the pressure regulator P3, the substrate W is transferred while the decompressed states of the exposure space S1 in the exposure device 30 and the inside of the dry lithography device 20 are maintained. Accordingly, the load lock chamber configured to switch its internal pressure between the atmospheric pressure state and the decompressed state need not be provided in the transfer path of the substrate W between the dry lithography device 20 and the exposure device 30. As a result, in the transfer of the substrate W, the time required for the switching of the internal pressure of the load lock chamber is omitted, which makes it possible to perform the dry lithography process more efficiently.

### Modification Examples

It will be appreciated that the disclosure in the present specification is illustrative in all aspects and is not intended to be limiting. Various omissions, replacement and modifications may be made without departing from the scope and spirit of the claims.

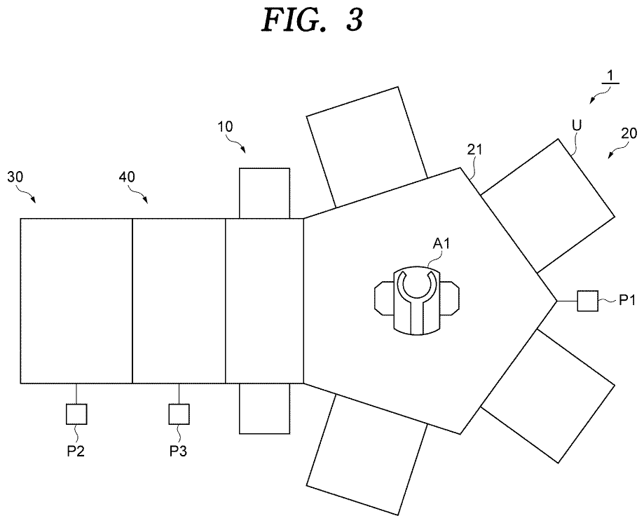

(1) As illustrated in FIG. 3, the dry lithography device 20 may be configured as a multi-chamber cluster in which the transfer section 21 equipped with the transfer arm A1 is disposed at the center and the plurality of lithography chambers U are connected around the transfer section 21. As illustrated in FIG. 3, the carry-in/out station 10 may be disposed between the dry lithography device 20 and the connection station 40. Alternatively, the transfer section 21 and the connection station 40 may be directly connected without the carry-in/out station 10 therebetween, and the carry-in/out station 10 may be connected around the transfer section 21.

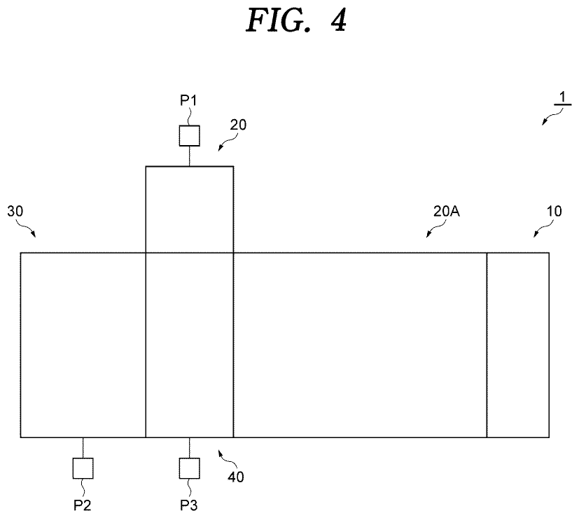

(2) As illustrated in FIG. 4, the dry lithography device 20 may be disposed on a lateral side of the connection station 40, and a wet lithography device 20A may be disposed between the carry-in/out station 10 and the connection station 40. The wet lithography device 20A is configured to perform a lithography process on the substrate mainly by a processing liquid. To this end, the internal pressure of the wet lithography device 20A is set to a pressure equivalent to the atmospheric pressure, or a positive pressure. Here, in the present specification, the lithography process by the wet lithography device 20A includes various types of processes such as, but not limited to, a process of forming a resist film on the surface of the substrate W, a developing process on the resist film after being exposed, a heat treatment on the substrate W, an etching process on the substrate W, and so forth (excluding an exposure process on the resist film). Further, in the lithography process on the substrate W in the wet lithography device 20A, a process using a gas may be partially performed on the substrate W. In the example of FIG. 4, the pressure regulator P3 may regulate the internal pressure of the transfer space S2 between the atmospheric pressure or positive pressure and the pressure equivalent to the internal pressure of the exposure space S1 (that is, within a range from the atmospheric pressure or positive pressure to the ultra-high vacuum).

According to the example of FIG. 4, the substrate W processed in the wet lithography device 20A may be carried into the exposure device 30 via the connection station 40, or the substrate W processed in the exposure device 30 may be carried out to the wet lithography device 20A via the connection station 40. That is, as the internal pressure of the transfer space S2 is regulated by the pressure regulator P3 between the atmospheric pressure or positive pressure to a pressure less than that, the substrate W processed under the atmospheric pressure or positive pressure can be carried into or out of the exposure device 30. Therefore, the substrate processing system 1 is capable of handling various types of substrates W, which makes it possible to improve the efficiency of a substrate processing.

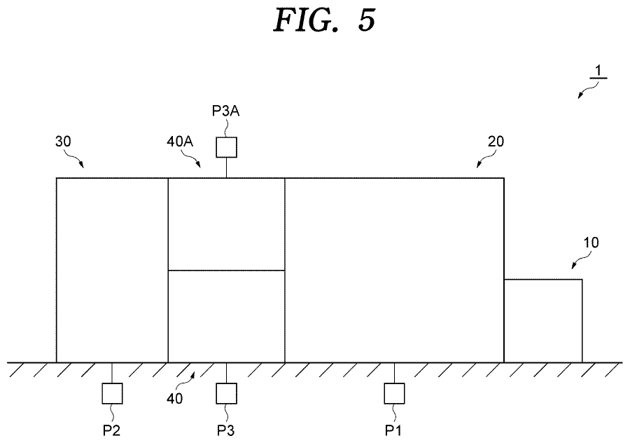

(3) As illustrated in FIG. 5, the substrate processing system 1 may be further equipped with a connection station 40A (additional connector) and a pressure regulator P3A. The connection stations 40 and 40A may be stacked on top of each other in a vertical direction. The connection station 40A may be configured to connect the dry lithography device 20 and the exposure device 30. The connection station 40A is configured in the same way as the connection station 40, and may include a pressure regulation chamber and a transfer chamber (both are not shown). Like the connection station 40, the connection station 40A may include a plurality of pressure regulation chambers arranged in a horizontal direction or a vertical direction. The insides of the pressure regulation chamber and the transfer chamber may constitute a transfer space (not shown) through which the substrate W is transferred. In the example of FIG. 5, the transfer space of the connection station 40A is adjacent to the internal space of the dry lithography device 20, and is also adjacent to the exposure space S1 of the exposure device 30.

The pressure regulator P3A is connected to the pressure regulation chamber and the transfer chamber of the connection station 40A. The pressure regulator P3A may be configured to regulate the internal pressure of the transfer space of the pressure regulation chamber and the transfer chamber of the connection station 40A between the atmospheric pressure or positive pressure and a pressure less than that based on a control signal from the controller Ctr. The pressure regulator P3A may regulate the internal pressure of the transfer space between the atmospheric pressure or positive pressure and the pressure equivalent to the internal pressure of exposure space S1 (that is, within a range from the atmospheric pressure or positive pressure to the ultra-high vacuum).

According to the example of FIG. 5, a substrate processed in an external device, for example, can be carried into the exposure device 30 via the dry lithography device 20 and the connection station 40A. According to the example of FIG. 5, the substrate W processed in the exposure device 30 can be transferred to the external device via the dry lithography device 20 and the connection station 40A.

When transferring the substrate W between the connection station 40A and the external device, the pressure regulator P3A may be operated so that the internal pressure of the connection station 40A becomes equivalent to the atmospheric pressure or positive pressure. In this case, to suppress the decompressed space inside the dry lithography device 20 from being opened to the atmosphere, a passage for the transfer of the substrate, which is separated from the decompressed space of the dry lithography device 20 and communicates with the connection station 40A, is provided inside the dry lithography device 20. Meanwhile, when the substrate W is transferred between the connection station 40A and the exposure device 30, the pressure regulator P3A may be operated so that the internal pressure of the connection station 40A becomes equivalent to the internal pressure of the exposure space S1 of the exposure device 30.

In this way, as the internal pressure of the transfer space of the connection station 40A is regulated by the pressure regulator P3A between the atmospheric pressure or positive pressure and a pressure less than that, the substrate W processed under the atmospheric pressure or positive pressure can be carried into or out of the exposure device. Therefore, the substrate processing system 1 is capable of handling various types of substrates, so that the efficiency of the substrate processing may be improved.

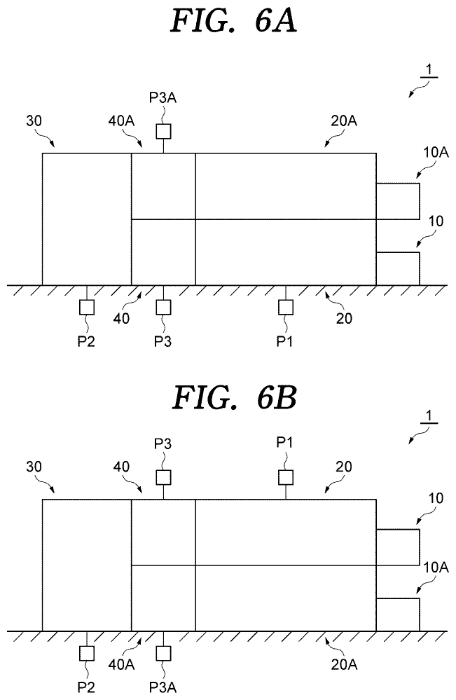

(4) As illustrated in FIG. 6A and FIG. 6B, the substrate processing system 1 may be further equipped with a carry-in/out station 10A, the wet lithography device 20A, the connection station 40A, and the pressure regulator P3A. The carry-in/out station 10A may be configured in the same way as the carry-in/out station 10. The wet lithography device 20A may have the same configuration as the wet lithography device 20A illustrated in FIG. 4. The connection station 40A and the pressure regulator P3A may each have the same configurations as the connection station 40A and the pressure regulator P3A shown in FIG. 5. The carry-in/out station 10A, the wet lithography device 20A, and the connection station 40A may be arranged in a row in this order in a horizontal direction.

According to the example of FIG. 6A and FIG. 6B, the substrate W processed in the wet lithography device 20A can be carried into the exposure device 30 via the connection station 40A, or the substrate W processed in the exposure device 30 can be carried out to the wet lithography device 20A via the connection station 40A. That is, as the internal pressure of the transfer space of the connection station 40A is regulated by the pressure regulator P3A between the atmospheric pressure or positive pressure and a pressure less than that, the carry-in/carry-out of the substrate W processed under the atmospheric pressure or positive pressure into/from the exposure device 30 is enabled. Therefore, the substrate processing system 1 is capable of handling various types of substrates W, which makes it possible to better the efficiency of the substrate processing.

As illustrated in FIG. 6A and FIG. 6B, the carry-in/out station 10, the dry lithography device 20, and the connection station 40 may constitute a single first module. The carry-in/out station 10A, the wet lithography device 20A, and the connection station 40A may constitute a separate second module. In the substrate processing system 1, the first module and the second module may be stacked in a vertical direction. In this case, since the connection stations 40 and 40A are arranged in the vertical direction, the footprint of the connection stations 40 and 40A with respect to a bottom of the substrate processing system 1 is reduced, when viewed from the top. Therefore, the substrate processing apparatus can be made compact. FIG. 6A shows an example of the substrate processing system 1 in which the second module is stacked on top of the first module. FIG. 6B shows an example of the substrate processing system 1 in which the first module is stacked on top of the second module.

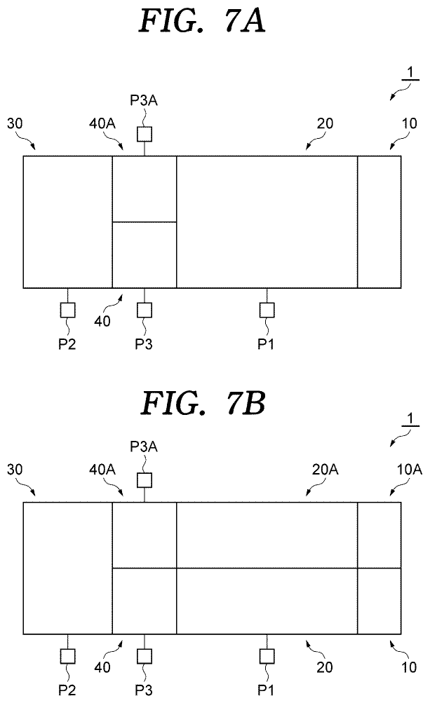

(5) As illustrated in FIG. 7A and FIG. 7B, the substrate processing system 1 may be further equipped with the connection station 40A and the pressure regulator P3A. The connection stations 40 and 40A may be arranged in a horizontal direction. In this case, since the connection stations 40 and 40A are arranged in the horizontal direction, it becomes possible to simplify an architecture for distributing and transferring substrates W to these stations. Furthermore, according to the example shown in FIG. 7A and FIG. 7B, as the internal pressure of the transfer space of the connection station 40A is regulated by the pressure regulator P3A between the atmospheric pressure or positive pressure and a pressure less than that, the same as in the examples shown in FIG. 5, FIG. 6A and FIG. 6B, it becomes possible to carry the substrate W processed under the atmospheric pressure or positive pressure into/out of the exposure device. Therefore, the substrate processing system 1 is capable of handling various types of substrates, which makes it possible to improve the efficiency of the substrate processing.

As depicted in FIG. 7A, the connection station 40A may be configured to connect the dry lithography device 20 and the exposure device 30. The connection station 40A is configured in the same way as the connection station 40, and may include a pressure regulation chamber and a transfer chamber (both are not shown). The insides of the pressure regulation chamber and the transfer chamber may constitute a transfer space (not shown) through which the substrate W is transferred. In the example of FIG. 5, the transfer space of the connection station 40A is adjacent to the internal space of the dry lithography device 20 and is adjacent to the exposure space S1 of the exposure device 30. In the example of FIG. 7A, a passage for the transfer of the substrate, which is separated from the decompressed space of the dry lithography device 20 and communicates with the connection station 40A, may be provided inside the dry lithography device 20 so that the decompressed space may not be opened to the atmosphere, the same as in the example of FIG. 5.

As illustrated in FIG. 7B, the carry-in/out station 10, the dry lithography device 20, and the connection station 40 may constitute a single first module, the same as in the examples of FIG. 6A and FIG. 6B. Further, the carry-in/out station 10A, the wet lithography device 20A, and the connection station 40A may constitute a separate second module, the same as in the examples of FIG. 6A and FIG. 6B. Meanwhile, unlike in the examples of FIG. 6A and FIG. 6B, the first module and the second module may be arranged in a horizontal direction.

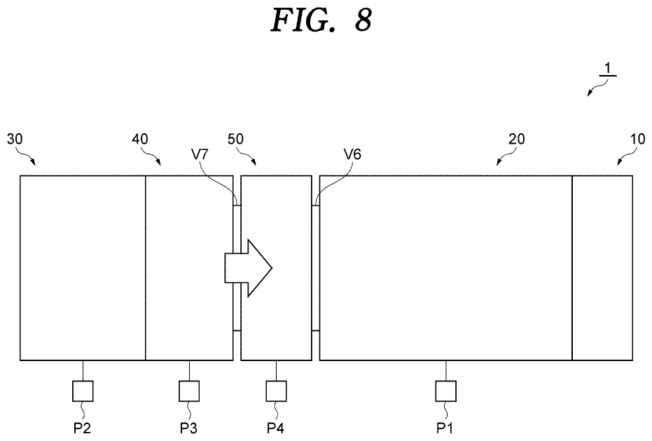

(6) As illustrated in FIG. 8, the substrate processing system 1 may be further equipped with an auxiliary connection station 50 (auxiliary connector) and a pressure regulator P4. The auxiliary connection station 50 may be disposed between the dry lithography device 20 and the connection station 40. A gate valve V6 may be provided between the auxiliary connection station 50 and the dry lithography device 20. A gate valve V7 may be provided between the auxiliary connection station 50 and the connection station 40. The gate valves V6 and V7 are configured to be opened and closed based on a control signal from the controller Ctr. The gate valves V6 and V7 are opened when the substrate W is transferred between the dry lithography device 20 and the connection station 40.

The pressure regulator P4 (suction device) may include an exhaust pump. The pressure regulator P4 may be operated with the gate valves V6 and V7 opened when the substrate W is transferred between the dry lithography device 20 and the connection station 40. By the operation of this pressure regulator P4, an airflow heading toward the auxiliary connection station 50 from the connection station 40 is formed (see an arrow in FIG. 8). For this reason, the pressure regulator P4 may regulate the internal pressure of the auxiliary connection station so that it becomes equal to or higher than the pressure of the internal space of the dry lithography device 20 and lower than the pressure of the transfer space S2 of the connection station 40. In this case, since the airflow heading toward the auxiliary connection station 50 is formed by the pressure regulator P4, it becomes difficult for a microscopic substance and a gas generated during the process on the substrate W in the dry lithography device 20 to reach the connection station 40 beyond the auxiliary connection station 50. Therefore, contamination of the inside of the apparatus due to the microscopic substance and the gas may be suppressed.

The pressure regulator P4 (additional pressure regulator) may further include a gas inlet valve (not shown) in addition to the exhaust pump. The pressure regulator P4 (additional pressure regulator) may be configured to regulate the internal pressure of the auxiliary connection station 50 between the pressure of the internal space of the dry lithography device 20 and the pressure of the exposure space S1 of the exposure device 30. For example, when the substrate W is transferred between the dry lithography device 20 and the auxiliary connection station 50, the pressure regulator P4 may be operated so that the internal pressure of the auxiliary connection station 50 becomes equal to the pressure of the internal space of the dry lithography device 20. In this state, by opening the gate valve V6 while keeping the gate valve V7 closed, the substrate W may be carried in and out between the dry lithography device 20 and the auxiliary connection station 50. Meanwhile, when the substrate W is transferred between the auxiliary connection station 50 and the connection station 40, the pressure regulator P4 may be operated so that the internal pressure of the auxiliary connection station 50 becomes equal to the pressure of the transfer space S2 of the connection station 40. In this state, by opening the gate valve V7 while keeping the gate valve V6 closed, the substrate W may be carried in and out between the auxiliary connection station 50 and the connection station 40.

According to the example of FIG. 8, the pressure of the relatively narrow space inside the auxiliary connection station 50, not the pressure of the relatively large space inside the exposure device 30 or the dry lithography device 20, is regulated by the pressure regulator P4. For this reason, the pressure regulation is performed promptly in the auxiliary connection station 50, and the substrate W is transferred between the exposure device 30 and the dry lithography device 20 while the relationship between the internal pressure of the exposure device 30 and the internal pressure of the dry lithography device 20 is maintained. Accordingly, when transferring the substrate W, the time required for the regulation of the internal pressures of the exposure device 30 and the dry lithography device 20 is omitted, which makes it possible to perform the dry lithography process more efficiently.

(7) In the above-described examples, a moisture supply (not shown) configured to supply moisture to the substrate W may be provided inside the connection station 40 or the lithography device (including the respective cases of the dry lithography device 20 and the wet lithography device 20A). By way of example, the moisture supply may be configured to supply moisture in a gaseous or liquid state toward the substrate W in a space where the substrate W is disposed. The moisture supply may be configured to supply moisture to a positive pressure space or may be configured to supply moisture to a decompressed space. The substrate W to which the moisture is supplied may be either the substrate W before being subjected to the exposure processing or the substrate W after being subjected to the exposure processing.

### Other Examples

Example 1. A substrate processing apparatus includes a dry lithography device configured to perform a lithography process on a substrate mainly by a gas; and a connector configured to connect the dry lithography device to an exposurer configured to expose the substrate. The connector includes a transfer space which is adjacent to an exposure space of the exposurer and through which the substrate is transferred between the exposurer and the dry lithography device. In this case, the connector is adjacent to the exposurer, and the substrate is transferred between the dry lithography device and the exposurer through the transfer space of the connector. For this reason, a transfer path of the substrate between the dry lithography device and the exposurer is shortened. Therefore, a dry lithography process can be carried out efficiently.

Example 2. The substrate processing apparatus of Example 1 further includes a decompressor configured to decompress the transfer space to a pressure less than an atmospheric pressure during transfer of the substrate through the transfer space. Here, an exposure space within the exposurer and the inside of the dry lithography device are typically decompressed to a pressure less than an atmospheric pressure. In Example 2, since the transfer space is decompressed by the decompressor, the substrate is transferred while the decompressed states of the exposure space of the exposurer and the inside of the dry lithography device are maintained. Accordingly, a load lock chamber configured to switch its internal pressure between an atmospheric pressure state and a decompressed state need not be provided in the transfer path of the substrate between the dry lithography device and the exposurer. As a result, in the transfer of the substrate, the time required for the switching of the internal pressure of the load lock chamber is omitted, which makes it possible to perform the dry lithography process more efficiently.

Example 3. The substrate processing apparatus of Example 1 or Example 2 further includes an additional connector configured to connect the exposurer and the dry lithography device; and a pressure regulator. The additional connector includes an additional transfer space which is adjacent to the exposure space of the exposurer and through which the substrate is transferred between the exposurer and the dry lithography device. The pressure regulator is configured to regulate an internal pressure of the additional transfer space between an atmospheric pressure and a pressure less than the atmospheric pressure during transfer of the substrate through the additional transfer space. In this case, a substrate processed in an external device, for example, can be carried into the exposurer via the dry lithography device and the pressure regulator or the substrate processed in the exposurer can be carried out to the external device via the dry lithography device and the pressure regulator. That is, as the internal pressure of the additional transfer space is regulated between the atmospheric pressure and the pressure less than that by the pressure regulator, the carry-in/carry-out of the substrate processed under the atmospheric pressure to/from the exposurer is enabled. Therefore, the substrate processing apparatus is capable of handling various types of substrates, which makes it possible to improve the efficiency of a substrate processing.

Example 4. The substrate processing apparatus of Example 1 or Example 2 further includes a wet lithography device configured to perform a lithography process on the substrate mainly by a processing liquid; an additional connector configured to connect the exposurer and the wet lithography device; and a pressure regulator. The additional connector includes an additional transfer space which is adjacent to the exposure space of the exposurer and through which the substrate is transferred between the exposurer and the wet lithography device. The pressure regulator is configured to regulate an internal pressure of the additional transfer space between an atmospheric pressure and a pressure less than the atmospheric pressure during transfer of the substrate through the additional transfer space. In this case, the substrate processed in the wet lithography device can be carried into the exposurer via the pressure regulator, or the substrate processed in the exposurer can be carried out to the wet lithography device via the pressure regulator. That is, as the internal pressure of the additional transfer space is regulated between the atmospheric pressure and the pressure less than that by the pressure regulator, the carry-in/carry-out of the substrate processed under the atmospheric pressure to/from the exposurer is enabled. Therefore, the substrate processing apparatus is capable of handling various types of substrates, which makes it possible to improve the efficiency of the substrate processing.

Example 5. In the substrate processing apparatus of Example 3 or Example 4, the connector and the additional connector are arranged in a vertical direction. In this case, since the connector and the additional connector are arranged in the vertical direction, the footprint of the connectors with respect to a bottom of the substrate processing apparatus is reduced, when viewed from the top. Therefore, the substrate processing apparatus can be made compact.

Example 6. In the substrate processing apparatus of Example 3 or Example 4, the connector and the additional connector are arranged in a horizontal direction. In this case, since the connector and the additional connector are arranged in the horizontal direction, it becomes possible to simplify an architecture for distributing and transferring substrates to these connectors.

Example 7. The substrate processing apparatus of any one of Examples 1 to 6 further includes an auxiliary connector disposed between the connector and the dry lithography device; and a suction device configured to form an airflow heading toward the auxiliary connector from the connector. In this case, since the airflow heading toward the auxiliary connector is formed by the suction device, it becomes difficult for a microscopic substance and a gas generated during the processing of the substrate in the dry lithography device to reach the connector beyond the auxiliary connector. Therefore, contamination of the inside of the apparatus due to the microscopic substance and the gas may be suppressed.

Example 8. The substrate processing apparatus of any one of Examples 1 to 7 further includes an auxiliary connector disposed between the connector and the dry lithography device; and an additional pressure regulator configured to regulate an internal pressure of the auxiliary connector between an internal pressure of the exposurer and an internal pressure of the dry lithography device. Here, the exposure space inside the exposurer and the inside of the dry lithography device are typically decompressed to a pressure less than the atmospheric pressure, and the internal pressure of the exposure space within the exposurer tends to be set to be lower than the internal pressure of the dry lithography device. In Example 8, the pressure of the relatively narrow space inside the auxiliary connector, not the pressure of the relatively large space inside the exposurer or the dry lithography device, is regulated by the additional pressure regulator. For this reason, the pressure regulation is performed promptly in the auxiliary connector, and the substrate is transferred between the exposurer and the dry lithography device while the relationship between the internal pressure of the exposurer and the internal pressure of the dry lithography device is maintained. Accordingly, when transferring the substrate, the time required for the regulation of the internal pressures of the exposurer and the dry lithography device is omitted, which makes it possible to perform the dry lithography process more efficiently.

Example 9. A substrate processing method includes transferring a substrate to a dry lithography device configured to perform a lithography process on the substrate mainly by a gas; performing the lithography process on the substrate mainly by the gas in the dry lithography device; transferring the substrate after being subjected to the lithography process to an exposurer via a connector connected to the dry lithography device and the exposurer; and exposing the substrate in the exposurer. The connector includes a transfer space which is adjacent to an exposure space of the exposurer and through which the substrate is transferred between the exposurer and the dry lithography device. In this case, the same effects as in the substrate processing apparatus of Example 1 can be achieved.

In the substrate processing apparatus and the substrate processing method according to the exemplary embodiment, it is possible to carry out the dry lithography process efficiently.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a dry lithography device configured to perform a lithography process on a substrate mainly by a gas; and
a connector configured to connect the dry lithography device to an exposurer configured to expose the substrate,
wherein the connector includes a transfer space which is adjacent to an exposure space of the exposurer and through which the substrate is transferred between the exposurer and the dry lithography device.

2. The substrate processing apparatus of claim 1, further comprising:
a decompressor configured to decompress the transfer space to a pressure less than an atmospheric pressure during transfer of the substrate through the transfer space.

3. The substrate processing apparatus of claim 1, further comprising:
an additional connector configured to connect the exposurer and the dry lithography device; and
a pressure regulator,
wherein the additional connector includes an additional transfer space which is adjacent to the exposure space of the exposurer and through which the substrate is transferred between the exposurer and the dry lithography device, and
the pressure regulator is configured to regulate an internal pressure of the additional transfer space between an atmospheric pressure and a pressure less than the atmospheric pressure during transfer of the substrate through the additional transfer space.

4. The substrate processing apparatus of claim 1, further comprising:
a wet lithography device configured to perform a lithography process on the substrate mainly by a processing liquid;
an additional connector configured to connect the exposurer and the wet lithography device; and
a pressure regulator,
wherein the additional connector includes an additional transfer space which is adjacent to the exposure space of the exposurer and through which the substrate is transferred between the exposurer and the wet lithography device, and
the pressure regulator is configured to regulate an internal pressure of the additional transfer space between an atmospheric pressure and a pressure less than the atmospheric pressure during transfer of the substrate through the additional transfer space.

5. The substrate processing apparatus of claim 3,
wherein the connector and the additional connector are arranged in a vertical direction.

6. The substrate processing apparatus of claim 3,
wherein the connector and the additional connector are arranged in a horizontal direction.

7. The substrate processing apparatus of claim 1, further comprising:
an auxiliary connector disposed between the connector and the dry lithography device; and
a suction device configured to form an airflow heading toward the auxiliary connector from the connector.

8. The substrate processing apparatus of claim 1, further comprising:
an auxiliary connector disposed between the connector and the dry lithography device; and
an additional pressure regulator configured to regulate an internal pressure of the auxiliary connector between an internal pressure of the exposurer and an internal pressure of the dry lithography device.

9. A substrate processing method, comprising:
transferring a substrate to a dry lithography device configured to perform a lithography process on the substrate mainly by a gas;
performing the lithography process on the substrate mainly by the gas in the dry lithography device;
transferring the substrate after being subjected to the lithography process to an exposurer via a connector connected to the dry lithography device and the exposurer; and
exposing the substrate in the exposurer,
wherein the connector includes a transfer space which is adjacent to an exposure space of the exposurer and through which the substrate is transferred between the exposurer and the dry lithography device.
